(19) United States
(12) Patent Application Publication
(10) Pub. No.: US 2007/0267568 A1
(43) Pub. Date: Nov. 22, 2007

(54) Method for extending usage life span of infrared light sources for non-dispersive infrared (NDIR) gas sensing technology

(75) Inventor: Rich Wolleswinkel, De Meern (NL)

Correspondence Address: CHARLES E. BAXLEY, ESQ., 90 JOHN STREET, THIRD FLOOR, NEW YORK, NY, 10038, US

(73) Assignee: IR-TEC International Ltd.

(21) Appl. No.: 11/435,491

(22) Filed: May 16, 2006

(51) Int. Cl. H01L 31/00

(52) U.S. Cl. 250/214.1

(57) ABSTRACT

A method for extending a usage life span of infrared light sources for non-dispersive infrared (NDIR) gas sensing technology is applied for a gas detector. The method includes an intermittent measure of lighting up the light and an electric current control measure. The intermittent measure can alternatively light up the infrared light sources to make the infrared light sources work in turn. The electric current control measure is to detect voltages dropped one the infrared light sources and then to control an electric current capacity of a variable current source flowing to the infrared light sources in accordance with the detecting results, so as to fix a radiant power of the infrared light sources. Hence the two infrared lights sources can share usage loading to provide the stable radiant power to achieve an objective of extending the usage life span of the infrared light sources.

### BACKGROUND OF THE INVENTION

1. Field of the Invention

The invention relates in general to a method for extending a usage life span of infrared light sources, and more particularly to a method for extending a usage life span of infrared light sources for non-dispersive infrared (NDIR) gas sensing technology.

2. Description of the Related Art

Along with an increase of production density, operators may be infected with respiratory diseases if a ventilation condition in a factory is bad. In view of this point, factory owners propose a particle measuring apparatus as shown in an example of U.S. Pat. No. 4,420,256 in FIG. 3. With reference to FIG. 3, a measuring apparatus comprises a casing (not shown in the diagram), a light source (3), a first light detector (6), a second light detector (7) and a calculating circuit (9). A measuring channel (2) is formed in the casing to let a plurality of dust particles (1) in the air flow through the channel (2) by a flowing medium. The light source (3) is installed inside the casing for illuminating the dust particles (1) with a light beam having an axis in a direction different from the direction of flow of the medium. The first light detector (6) is positioned along the axis of the light beam so as to receive light not scattered and not absorbed by the dust particles (1). The second light detector (7) is positioned not along the axis of light beam of the light source (3) so as to only receive light reflected by the dust particles (1). The calculating circuit (9) is positioned outside the casing coupled to the two light detectors (6, 7) to compare two received light strength of the two light detectors (6, 7), so as to calculate a concentration of the dust particles (1) in the air.

Many hidden risks exist in our daily lives regardless of living environment or working environment, such as bad ventilation in the living environment or in the public places may cause gas or carbon monoxide poisoning. Further, bad ventilation in the factories is likely to cause toxic gas poisoning or excess concentration of carbon dioxide can be harmful to health. Hence the aforesaid measuring apparatus also can be used to detect the concentration of carbon monoxide, carbon dioxide and the like.

In order to ensure the air quality conditions keep normal in the living environment, public places or working environment, the aforesaid measuring apparatus has to operate for a long time. Hence a usage life span of light sources is often not long due to long-term operation. Besides, the light sources have to be lightened up periodically by instantly lighting up the light sources from a low temperature to provide the long-term operation. Thus the usage life span of the light sources becomes even shortened due to a thermal shock against the light sources.

Therefore, the light sources belong to a consumptive component in comparison with other components of the measuring apparatus. The usage life span of the light sources is a critical point for the measuring apparatus that whether the measuring apparatus can provide the long-term operation.

### SUMMARY OF THE INVENTION

The present invention provides a method for extending a usage life span of infrared light sources for non-dispersive infrared (NDIR) gas sensing technology, which is applied for a NDIR gas detector.

In order to achieve the above objective, a main feature of the present invention is to make the NDIR detector include a plurality of infrared light sources to emit infrared rays. A light detector receives the infrared rays passing through the air, and then a microprocessor determines strength of the received infrared rays of the light detector to calculate a concentration of a specific gas in the air. The microprocessor is built-in with a control process as follows.

An intermittent measure of lighting up the light can alternatively light up the infrared light sources to make the infrared light sources work in turn. Moreover, an electric current control measure is to detect voltages dropped on the infrared light sources and then to control an electric current capacity of a variable current source inputted to the infrared light sources according to the detecting results.

The present invention controls the two infrared light sources to operate in turn to share the usage loading of the infrared light sources, so as to achieve the objective of extending the usage life span of the infrared light sources. In addition, according to the detecting voltages of the infrared light sources, electric current capacity delivered to the infrared light sources is controlled. In this way, a radiant power of the infrared light sources is fixed; so as to avoid changing a resistance value to cause a variation of the radiant power after the infrared light sources is used for a long time. The stable radiant power not only can decrease a damage possibility of the infrared light sources, but also can make the infrared light sources continue to emit the infrared rays of constant brightness. Hence an error of calculating a concentration of a specific gas in the air can be avoided.

The intermittent measure of lighting up the light controls a plurality of switches respectively connected to the microprocessor and the infrared light sources by way of making the switches on and off alternatively, so as to light up the infrared lights sources alternatively.

The electric current control measure further controls the electric current capacity of the variable current source gradually increasing flowing to the infrared light source to be lighted up.

The electric current capacity that the electric current control measure maintains to flow though the unlighted infrared light source is approximately 10% to 15% of the required electric current capacity of the lightened infrared light source.

### BRIEF DESCRIPTION OF THE DRAWINGS

FIG. 1 is a block diagram of an embodiment of a non-dispersive infrared (NDIR) gas sensor in accordance with the present invention;

FIG. 2 shows a flow chart of the non-dispersive infrared (NDIR) gas sensor applied to a carbon dioxide detector in accordance with the present invention applied to a carbon dioxide detector.

FIG. 3 is a block diagram of a conventional particle measuring apparatus in accordance with the prior art.

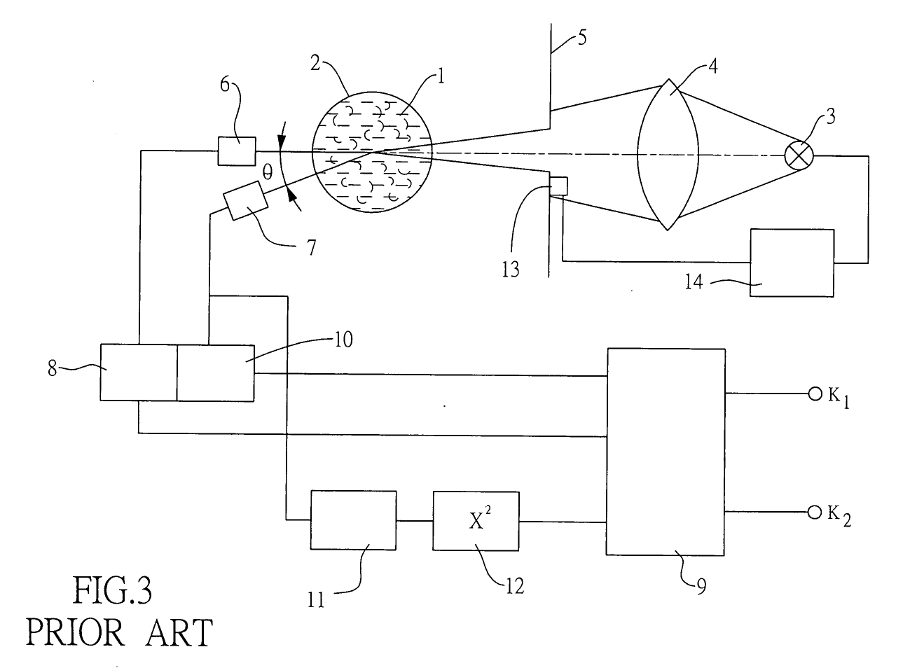

### DETAILED DESCRIPTION OF THE INVENTION

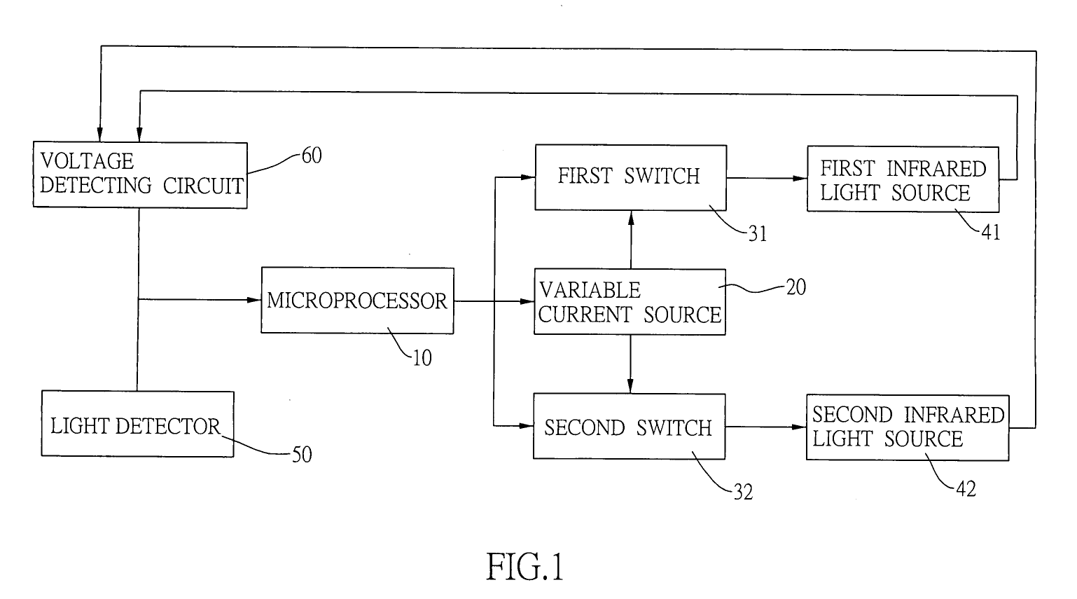

With reference to FIG. 1, an embodiment of a non-dispersive infrared (NDIR) gas sensor in accordance with the present invention is applied to a carbon dioxide detector.

The carbon dioxide detector includes a casing, a microprocessor (10), a variable current source (20), a first switch (31), a second switch (32), a first infrared light source (41), a second infrared light source (42), a reflector, a light detector (50) and a voltage detecting circuit 60.

A measuring channel is formed inside the casing. The air can flow from one end of the measuring channel to enter casing and then flowing out of the casing from the other end of the measuring channel. The microprocessor (10) is configured inside the casing, which is a processing center of the carbon dioxide sensor. The variable current source (20) is coupled to a power source and the microprocessor (10). The microprocessor (10) can control an output electric current capacity the variable current source (20).

The first and second witches (31, 32) are configured inside the casing connected to the microprocessor (10) and the variable current source (20).

The first and second infrared light sources (41, 42) are configured inside the casing and respectively connected to the first and second witches (31, 32). Therefore, the infrared light sources (41, 42) are respectively connected to the variable current source (20) through the first and second switches (31, 32). The microprocessor (10) can control ON and OFF statuses of the first and second witches (31, 32), so as to light up or to turn off the first and second infrared light sources (41, 42).

The reflector is configured inside the casing facing the first and second infrared light sources (41, 42), so as to reflect the infrared light of the first and second infrared light sources (41, 42).

The light detector (50) is configured inside the casing coupled to the microprocessor (10) for receiving the reflected infrared light of the reflector, and then to send corresponding strength of the received infrared light to the microprocessor (10). The voltage detecting circuit (60) is cross-connected to two terminals of each infrared light source (41, 42) and also connected to the microprocessor (10). The voltage detecting circuit (60) is used for measuring two voltages respectively dropped on the first and second infrared light sources (41, 42), and then to send the voltages to the microprocessor (10). Since the microprocessor (10) controls the variable current source (20), the microprocessor (10) can calculate power of each of the infrared light sources (4 1, 42) by the formula: power=voltage*current (P=V×I).

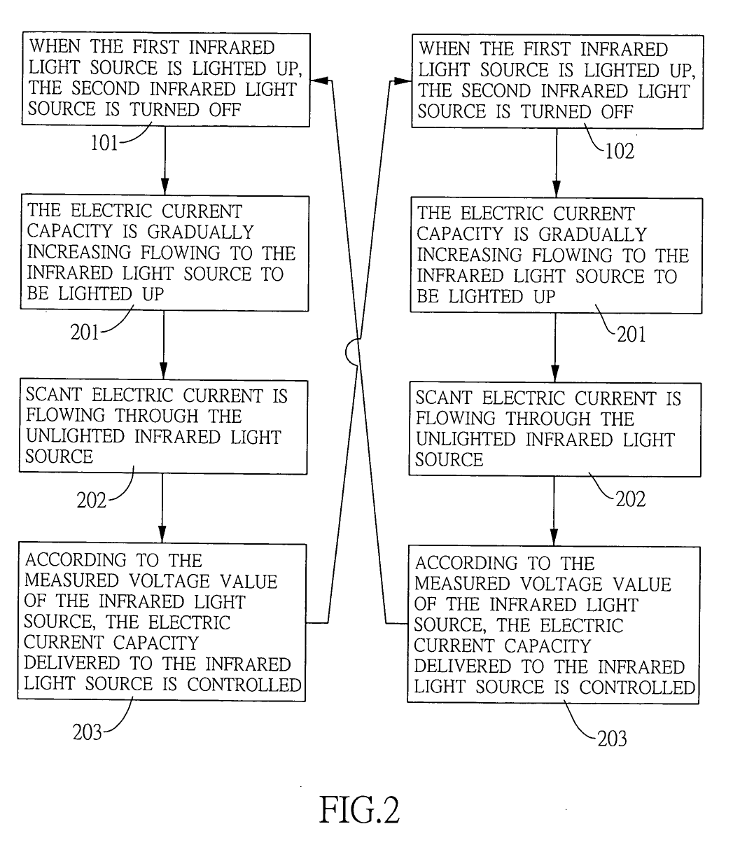

Further, a method of the present invention is to build-in a control process in the microprocessor (10). With reference to FIG. 2, the control process includes an intermittent measure of lighting up a light and an electric current control measure.

The intermittent measure of lighting up the light can alternatively control the ON status or OFF status of the first and second switches (31, 32). Hence when the first infrared light source (41) is lighted up (ON status), the second infrared light source (42) is turned off (OFF status) as shown in a step (101) in the diagram. On the other hand, when the second infrared light source (42) is lighted up (ON status), the first infrared light source (41) is turned off (OFF status) as shown in a step (102). In this way, the first and second infrared light sources (41, 42) can work in turn to share usage loading, so as to achieve the objective of extending the usage life span of the first and second infrared light sources (41, 42).

The electric current control measure is to detect two voltages dropped on the first and second infrared light sources (41, 42), and then to control an electric current capacity of a variable current source (20) flowing to the first and second infrared light sources (41, 42) in accordance with the detecting results. The electric current control measure includes the following three functions.

First of all, the electric current control measure controls the electric current capacity of the variable current source (20) gradually increasing current flowing to the infrared light source to be lighted up as shown in a step (201). In this way, the first and second infrared light sources (41, 42) can avoid a thermal shock due to sudden bright when the light source emits infrared rays.

Secondly, the electric current control measure further controls the variable current source (20) to have scant electric current flowed through the unlighted infrared light source as shown in a step (202). The electric current capacity that the flows though the unlighted infrared light source is approximately 10% to 15% of the required electric current capacity of the lightened infrared light source. Thereby the unlighted infrared light source has dim brightness. In this way, when the unlighted infrared light source takes turn to emit the infrared rays, not only lighting time can be decreased, but also the infrared light source can avoid the thermal shock for the infrared light source is in a preheated status.

Thirdly, according to the detecting results of the voltage detecting circuit (60) of the infrared light sources, the electric current capacity supplied to the infrared light sources by the variable current source (20) is controlled as shown in a step (203). In this way, the radiant power of the infrared light sources is fixed; so as to avoid changing a resistance value to cause a variation of the radiant power after the infrared light sources is used for a long time. The stable radiant power not only can decrease a damage possibility of the infrared light sources, but also can make the infrared light sources continue to emit the infrared rays of constant brightness. Hence an error of calculating a concentration of a specific gas in the air can be avoided.

It can be clearly understood from the above description that the present invention controls the two infrared light sources to operate in turn to share the usage loading of the infrared light sources, so as to achieve the objective of extending the usage life span of the infrared light sources. In addition, the damage possibility of the infrared light sources is decreased by controlling the electric current capacity flowing to the infrared light sources to fix the radiant power of the infrared light sources. Moreover, the electric current control measure that controls the electric current capacity of the variable current source increasingly flowing to the infrared light source to be lighted up can avoid a thermal shock due to sudden bright when the light source emits infrared rays. The electric current control measure also controls the variable current source to have scant electric current flow through the unlighted infrared light source to avoid the thermal shock. The electric current capacity that the flows though the unlighted infrared light source is approximately 10% to 15% of the required electric current capacity of the lightened infrared light source.

Therefore, the method for extending the usage life span of the infrared light sources for non-dispersive infrared (NDIR) gas sensing technology of the present invention indeed includes features of good utility and unobviousness to meet the requirements of a patent.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method for extending a usage life span of infrared light sources for non-dispersive infrared (NDIR) gas sensing technology, which is applied for a NDIR gas detector, wherein the NDIR detector comprises a microprocessor, a plurality of infrared light sources connected to the microprocessor and emitting infrared rays to air, and a light detector connected to the microprocessor, wherein a light detector receives the infrared rays passing through the air, and then the microprocessor determines strength of the received infrared rays of the light detector to calculate a concentration of a specific gas in the air, wherein the microprocessor is built-in with a control process and the control process comprises steps of:
an intermittent measure of lighting up a light which alternatively lights up the infrared light sources to make the infrared light sources work in turn; and
an electric current control measure to detect voltages dropped on each of the infrared light sources and then to control an electric current capacity of a variable current source inputted to the lighted infrared light sources according to the voltages.

2. The method for extending a usage life span of infrared light sources for non-dispersive infrared (NDIR) gas sensing technology as claimed in claim 1, wherein the microprocessor are further connected to the infrared light sources through a plurality of switches, and the intermittent measure of lighting up the light further controls ON status and OFF status of the switches respectively, so as to light up the infrared lights sources alternatively.

3. The method for extending a usage life span of infrared light sources for non-dispersive infrared (NDIR) gas sensing technology as claimed in claim 1, wherein the electric current control measure further controls the electric current capacity of the variable current source gradually increasing flowing to the infrared light source to be lighted up.

4. The method for extending a usage life span of infrared light sources for non-dispersive infrared (NDIR) gas sensing technology as claimed in claim 1, wherein the electric current control measure further controls the variable current source to output a scant electric current flow through the unlighted infrared light sources.

5. The method for extending a usage life span of infrared light sources for non-dispersive infrared (NDIR) gas sensing technology as claimed in claim 3, wherein the electric current control measure further controls the variable current source to output a scant electric current flow through the unlighted infrared light source.

6. The method for extending a usage life span of infrared light sources for non-dispersive infrared (NDIR) gas sensing technology as claimed in claim 4, wherein a capacity of the scant electric current inputted to the unlighted infrared light source is approximately 10% to 15% ofthe electric current capacity of the lightened infrared light source.

7. The method for extending a usage life span of infrared light sources for non-dispersive infrared (NDIR) gas sensing technology as claimed in claim 5, wherein a capacity of the scant electric current inputted to the unlighted infrared light source is approximately 10% to 15% of the electric current capacity of the lightened infrared light source.
